(19) United States
(12) Patent Application Publication
(10) Pub. No.: US 2024/0405512 A1
(43) Pub. Date: Dec. 5, 2024

(54) WAVELENGTH VARIABLE LASER

(71) Applicant: NEC Corporation, Tokyo (JP)

(72) Inventor: Morio TAKAHASHI, Tokyo (JP)

(73) Assignee: NEC Corporation, Tokyo (JP)

(21) Appl. No.: 18/642,957

(22) Filed: Apr. 23, 2024

(30) Foreign Application Priority Data
May 31, 2023 (JP) 2023-090489

(51) Int. Cl. H01S 5/10; H01S 5/00

(52) U.S. Cl. CPC H01S 5/1096; H01S 5/0064; H01S 5/101

(57) ABSTRACT

Provided is a wavelength variable laser including: a semiconductor optical amplification element being arranged in such a way that both ends of a first optical amplification waveguide configured to amplify light by using a semiconductor are on the same element end surface being an anti-reflection termination surface; two optical waveguide elements being connected to both ends of the first optical amplification waveguide on the element end surface; and a first 2×2 branching unit, wherein the two optical waveguide elements are connected to two ports on one side of the first 2×2 branching unit.

### INCORPORATION BY REFERENCE

This application is based upon and claims the benefit of priority from Japanese patent application No. 2023-090489, filed on May 31, 2023, the disclosure of which is incorporated herein in its entirety by reference.

### TECHNICAL FIELD

The present disclosure relates to a wavelength variable laser.

### BACKGROUND ART

A waveguide-type wavelength variable laser formed on a semiconductor chip has been developed. International Patent Publication No. WO2019/156226 discloses a waveguide-type wavelength variable laser including a first reflection unit to which a laser is output, a second reflection unit that forms a laser resonator together with the first reflection unit, and a gain unit provided between the first reflection unit and the second reflection unit. In the wavelength variable laser, a waveguide is formed between the first reflection unit and the second reflection unit in such a way that an optical path is folded at an angle of substantially 180 degrees.

### SUMMARY

However, International Patent Publication No. WO2019/156226 does not disclose that the wavelength variable laser is connected to an additional optical amplification waveguide in order to further enhance optical output intensity of the wavelength variable laser or in order to adjust the optical output intensity to a desired value. Accordingly, an example object of the present disclosure is to provide a wavelength variable laser including an optical element that splits an optical path in order to couple an optical amplification waveguide to a waveguide-type wavelength variable laser.

In an example aspect of the present disclosure, a wavelength variable laser includes:
a semiconductor optical amplification element being arranged in such a way that both ends of a first optical amplification waveguide configured to amplify light by using a semiconductor are on the same element end surface being an anti-reflection termination surface; and
two optical waveguide elements being connected to both ends of the first optical amplification waveguide at the element end surface,
wherein the two optical waveguide elements are connected to two ports on one side of a first 2×2 branching unit.

### BRIEF DESCRIPTION OF DRAWINGS

The above and other aspects, features, and advantages of the present disclosure will become more apparent from the following description of certain example embodiments when taken in conjunction with the accompanying drawings, in which:

FIG. 1 is a block diagram illustrating a configuration of a wavelength variable laser according to a first example embodiment;

FIG. 2 is a schematic diagram illustrating a configuration of the wavelength variable laser according to the first example embodiment; and

FIG. 3 is a schematic diagram illustrating a configuration of a wavelength variable laser according to a second example embodiment.

### EXAMPLE EMBODIMENT

### Example Embodiments

Hereinafter, example embodiments of the present disclosure is described with reference to the drawings. However, the invention according to the claims is not limited to the following example embodiments. Further, not all of the configurations described in the example embodiments are essential as a solution to the problem. For clarity of explanation, the following description and the drawings are omitted and simplified as appropriate. In the drawings, the same element is denoted by the same reference sign, and redundant descriptions are omitted as necessary.

### Description of Wavelength Variable Laser According to First Example Embodiment

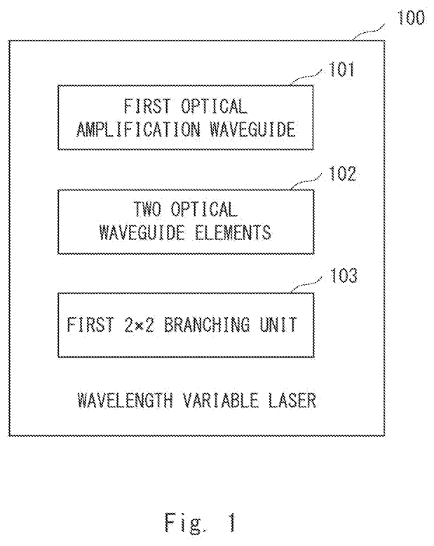

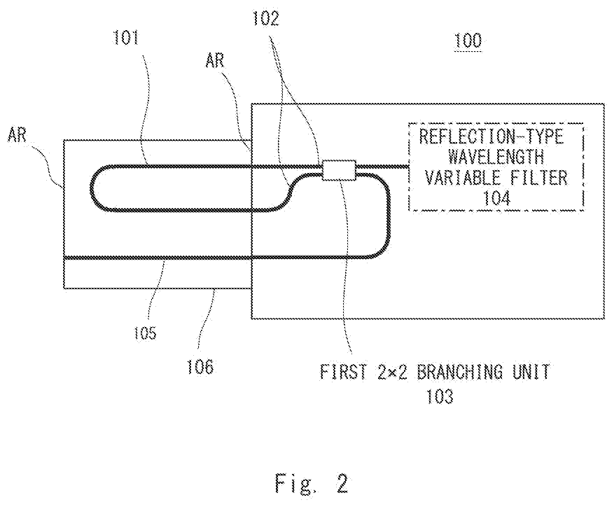

FIG. 1 is a block diagram illustrating a configuration of a wavelength variable laser according to a first example embodiment. FIG. 2 is a schematic diagram illustrating a configuration of a wavelength variable laser according to the first example embodiment. The wavelength variable laser according to the first example embodiment is described with reference to FIGS. 1 and 2. A wavelength variable laser 100 is a semiconductor laser capable of changing a wavelength.

As illustrated in FIGS. 1 and 2, the wavelength variable laser 100 includes a semiconductor optical amplification element including a first optical amplification waveguide 101, two optical waveguide elements 102, and a first 2×2 branching unit 103. As illustrated in FIG. 2, the wavelength variable laser 100 further includes a reflection-type wavelength variable filter 104 and a second optical amplification waveguide 105.

The first optical amplification waveguide 101 is a semiconductor optical amplifier for lasers which is formed on a semiconductor chip 106 and which is for oscillating a laser beam. The laser beam is, for example, infrared light having a wavelength of around 1500 nm. The first optical amplification waveguide 101 is U-shaped, and is arranged in such a way that both ends thereof are on the same element end surface of the semiconductor chip 106. The element end surface is an anti-reflection (AR) termination surface.

The two optical waveguide elements 102 are connected to both ends of the first optical amplification waveguide 101 at the element end surface. The two optical waveguide elements 102 pass laser beams incident on the first optical amplification waveguide 101 or emitted from the first optical amplification waveguide 101.

The first 2×2 branching unit 103 is a branching unit having two ports disposed on each side at both ends. Two ports on one side of the first 2×2 branching unit 103 are connected to the two optical waveguide elements 102.

According to the above-described configuration, a wavelength variable laser including an optical element that splits an optical path in order to couple an optical amplification waveguide to a semiconductor optical amplifier for lasers is provided. Further, since the semiconductor optical amplifier for lasers is coupled in a U-shape, it is possible to amplify a laser beam without excessive optical loss in the configuration.

Further, one of two ports on the other side of the first 2×2 branching unit 103 is connected to the reflection-type wavelength variable filter 104. The reflection-type wavelength variable filter 104 selectively reflects an incident laser beam, based on the wavelength of the laser beam. Therefore, the laser beam reciprocates between the U-shaped first optical amplification waveguide 101 and the reflection-type wavelength variable filter 104, and is thus amplified.

At this time, the first 2×2 branching unit 103 does not split at 50%. This is because, when splitting at 50%, all of the light inside a laser resonator is incident on the reflection-type wavelength variable filter 104, and no laser beam can be extracted to the outside of the laser resonator. Therefore, the first 2×2 branching unit 103 is preferably a directional coupler capable of adjusting the splitting ratio to other than 50%.

The other of the two ports on the other side of the first 2×2 branching unit 103 is connected to the second optical amplification waveguide 105. The second optical amplification waveguide 105 is a semiconductor optical amplifier for optical output that amplifies a laser beam by using a semiconductor. Both ends of the second optical amplification waveguide 105 are formed with anti-reflection termination surfaces. Therefore, a laser beam incident from one end of the second optical amplification waveguide 105 is amplified in the second optical amplification waveguide 105 and emitted from the other end of the second optical amplification waveguide 105.

The semiconductor chip 106 is configured of, for example, an optical amplification waveguide which is formed using GaAs, a desired impurity (such as Al or P), or the like, with a semiconductor material such as InP or the like as a substrate, and exhibits an optical gain by current injection. The second optical amplification waveguide 105 is formed on the same semiconductor chip 106 as the first optical amplification waveguide 101. Since the second optical amplification waveguide 105 is formed on the same semiconductor chip 106 as the first optical amplification waveguide 101, the size of the wavelength variable laser may be reduced. Further, since the second optical amplification waveguide 105 is formed on the same semiconductor chip 106 as the first optical amplification waveguide 101, light having the same wavelength may be efficiently amplified.

### Description of Wavelength Variable Laser According to Second Example Embodiment

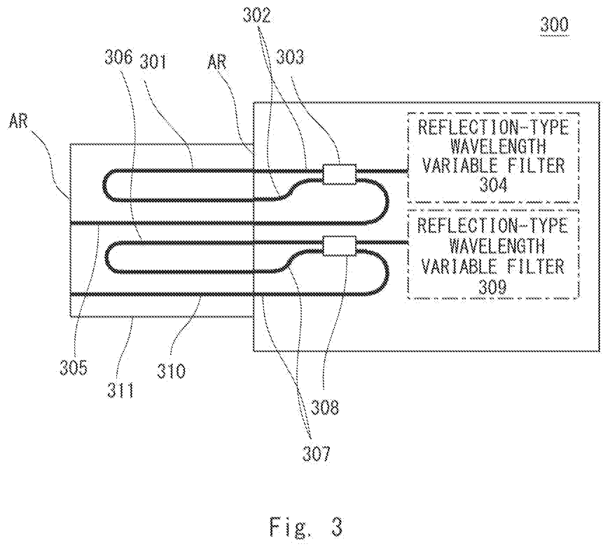

FIG. 3 is a schematic diagram illustrating a configuration of a wavelength variable laser according to a second example embodiment. The wavelength variable laser according to the second example embodiment is described with reference to FIG. 3.

As illustrated in FIG. 3, a wavelength variable laser 300 includes a semiconductor optical amplification element including a first optical amplification waveguide 301, two optical waveguide elements 302, and a first 2×2 branching unit 303. The wavelength variable laser 300 further includes a reflection-type wavelength variable filter 304 and a second optical amplification waveguide 305.

The wavelength variable laser 300 further includes a semiconductor optical amplification element including a third optical amplification waveguide 306, two optical waveguide elements 307, and a second 2×2 branching unit 308. The wavelength variable laser 300 further includes a reflection-type wavelength variable filter 309 and a fourth optical amplification waveguide 310.

The first optical amplification waveguide 301, the two optical waveguide elements 302, and the first 2×2 branching unit 303 of the wavelength variable laser 300 are the same optical elements as the first optical amplification waveguide 101, the two optical waveguide elements 102, and the first 2×2 branching unit 103 of the wavelength variable laser 100, respectively. The reflection-type wavelength variable filter 304 and the second optical amplification waveguide 305 of the wavelength variable laser 300 are the same as the reflection-type wavelength variable filter 104 and the second optical amplification waveguide 105 of the wavelength variable laser 100. Therefore, descriptions thereof are omitted.

The third optical amplification waveguide 306 is the same semiconductor optical amplifier for lasers as the first optical amplification waveguide 101. The second 2×2 branching unit 308 is the same branching unit as the first 2×2 branching unit 103. The second 2×2 branching unit 308 does not split at 50%. The second 2×2 branching unit 308 is preferably a directional coupler capable of adjusting the splitting ratio to a value other than 50%. Both ends of the third optical amplification waveguide 306 are connected to two ports on one side of the second 2×2 branching unit 308 via the two optical waveguide elements 307.

The fourth optical amplification waveguide 310 is the same semiconductor optical amplifier for optical output as the second optical amplification waveguide 105. Therefore, one end of the fourth optical amplification waveguide 310 is connected to the other of the two ports on the other side of the second 2×2 branching unit 308. The other end of the fourth optical amplification waveguide 310 is connected to the anti-reflection termination surface. Therefore, a laser beam incident from one end of the fourth optical amplification waveguide 310 is amplified in the fourth optical amplification waveguide 310, and emitted from the other end of the fourth optical amplification waveguide 310.

The reflection-type wavelength variable filter 309 is the same reflection-type wavelength variable filter as the reflection-type wavelength variable filter 104. Therefore, one of the two ports on the other side of the second 2×2 branching unit 308 is connected to the reflection-type wavelength variable filter 309.

The third optical amplification waveguide 306 and the fourth optical amplification waveguide 310 are formed on the same semiconductor chip 311 as the first optical amplification waveguide 301 and the second optical amplification waveguide 305. With such a configuration, a multi-channel wavelength variable laser 300 may be formed on the same semiconductor chip 311. Therefore, the size of the wavelength variable laser 300 may be reduced.

The present invention is not limited to the above-described example embodiments, and may be appropriately modified without departing from the scope and spirit. For example, a case where the connection between the optical elements constituting the second example embodiment is the same as the connection between the optical elements constituting the first example embodiment is assumed to be within the scope of the present disclosure.

According to the present disclosure, it is possible to provide a wavelength variable laser including an optical element that splits an optical path in order to couple an optical amplification waveguide to a semiconductor optical amplifier for lasers.

The first and second example embodiments may be combined as desirable by one of ordinary skill in the art.

While the disclosure has been particularly shown and described with reference to example embodiments thereof, the disclosure is not limited to these example embodiments. It will be understood by those of ordinary skill in the art that various changes in form and details may be made therein without departing from the spirit and scope of the present disclosure as defined by the claims.

The whole or part of the example embodiments disclosed above may be described as, but not limited to, the following supplementary notes.

### Supplementary Note 1

A wavelength variable laser including:
a semiconductor optical amplification element being arranged in such a way that both ends of a first optical amplification waveguide configured to amplify light by using a semiconductor are on the same element end surface being an anti-reflection termination surface;
two optical waveguide elements being connected to both ends of the first optical amplification waveguide on the element end surface; and
a first 2×2 branching unit, wherein the two optical waveguide elements are connected to two ports on one side of the first 2×2 branching unit.

### Supplementary Note 2

The wavelength variable laser according to supplementary note 1, wherein one of two ports on another side of the first 2×2 branching unit is connected to a reflection-type wavelength variable filter.

### Supplementary Note 3

The wavelength variable laser according to supplementary note 1, wherein another of two ports on another side of the first 2×2 branching unit is connected to one end of a second optical amplification waveguide.

### Supplementary Note 4

The wavelength variable laser according to supplementary note 3, wherein the first optical amplification waveguide is a laser semiconductor optical amplifier, and
the second optical amplification waveguide is an optical output semiconductor optical amplifier.

### Supplementary Note 5

The wavelength variable laser according to supplementary note 3, wherein the first optical amplification waveguide is formed on the same semiconductor chip as the second optical amplification waveguide.

### Supplementary Note 6

The wavelength variable laser according to supplementary note 5, wherein another end of the second optical amplification waveguide is connected to an anti-reflection termination surface of the semiconductor chip.

### Supplementary Note 7

The wavelength variable laser according to supplementary note 1, wherein the first 2×2 branching unit does not split at 50%.

### Supplementary Note 8

The wavelength variable laser according to supplementary note 1, wherein the first 2×2 branching unit is a directional coupler.

### Supplementary Note 9

The wavelength variable laser according to supplementary note 5, wherein
the semiconductor chip includes a third optical amplification waveguide and a fourth optical amplification waveguide,
the third optical amplification waveguide has both ends being connected to two ports on one side of a second 2×2 branching unit, and
one end of the fourth optical amplification waveguide is connected to one of two ports on another side of the second 2×2 branching unit.

### Supplementary Note 10

The wavelength variable laser according to supplementary note 9, wherein another of two ports on another side of the second 2×2 branching unit is connected to a reflection-type wavelength variable filter.

### Supplementary Note 11

The wavelength variable laser according to supplementary note 9, wherein
the third optical amplification waveguide is a laser semiconductor optical amplifier, and
the fourth optical amplification waveguide is an optical output semiconductor optical amplifier.

### Supplementary Note 12

The wavelength variable laser according to supplementary note 9, wherein another end of the fourth optical amplification waveguide is connected to the anti-reflection termination surface of the semiconductor chip.

### Supplementary Note 13

The wavelength variable laser according to supplementary note 9, wherein the second 2×2 branching unit does not split at 50%.

### Supplementary Note 14

The wavelength variable laser according to supplementary note 9, wherein the second 2×2 branching unit is a directional coupler.

What is claimed is:

1. A wavelength variable laser comprising:
a semiconductor optical amplification element being arranged in such a way that both ends of a first optical amplification waveguide configured to amplify light by using a semiconductor are on the same element end surface being an anti-reflection termination surface;
two optical waveguide elements being connected to both ends of the first optical amplification waveguide on the element end surface; and
a first 2×2 branching unit,
wherein the two optical waveguide elements are connected to two ports on one side of the first 2×2 branching unit.

2. The wavelength variable laser according to claim 1, wherein one of two ports on another side of the first 2×2 branching unit is connected to a reflection-type wavelength variable filter.

3. The wavelength variable laser according to claim 1, wherein another of two ports on another side of the first 2×2 branching unit is connected to one end of a second optical amplification waveguide.

4. The wavelength variable laser according to claim 3, wherein
the first optical amplification waveguide is a laser semiconductor optical amplifier, and
the second optical amplification waveguide is an optical output semiconductor optical amplifier.

5. The wavelength variable laser according to claim 3, wherein the first optical amplification waveguide is formed on the same semiconductor chip as the second optical amplification waveguide.

6. The wavelength variable laser according to claim 5, wherein another end of the second optical amplification waveguide is connected to an anti-reflection termination surface of the semiconductor chip.

7. The wavelength variable laser according to claim 1, wherein the first 2×2 branching unit does not split at 50%.

8. The wavelength variable laser according to claim 1, wherein the first 2×2 branching unit is a directional coupler.

9. The wavelength variable laser according to claim 5, wherein
the semiconductor chip includes a third optical amplification waveguide and a fourth optical amplification waveguide,
the third optical amplification waveguide has both ends being connected to two ports on one side of a second 2×2 branching unit, and
one end of the fourth optical amplification waveguide is connected to one of two ports on another side of the second 2×2 branching unit.

10. The wavelength variable laser according to claim 9, wherein another of two ports on another side of the second 2×2 branching unit is connected to a reflection-type wavelength variable filter.

11. The wavelength variable laser according to claim 9, wherein
the third optical amplification waveguide is a laser semiconductor optical amplifier, and
the fourth optical amplification waveguide is an optical output semiconductor optical amplifier.

12. The wavelength variable laser according to claim 9, wherein another end of the fourth optical amplification waveguide is connected to the anti-reflection termination surface of the semiconductor chip.

13. The wavelength variable laser according to claim 9, wherein the second 2×2 branching unit does not split at 50%.

14. The wavelength variable laser according to claim 9, wherein the second 2×2 branching unit is a directional coupler.
